(19) United States
(12) Patent Application Publication
(10) Pub. No.: US 2008/0047445 A1
(43) Pub. Date: Feb. 28, 2008

(54) Exposure device for the production of screen print stencils

(76) Inventor: Peter Berner, Rupperswill (CH)

Correspondence Address: WILLIAM COLLARD;COLLARD & ROE, P.C., 1077 NORTHERN BOULEVARD, ROSLYN, NY, 11576, US

(21) Appl. No.: 11/895,646

(22) Filed: Aug. 24, 2007

(30) Foreign Application Priority Data
Aug. 25, 2006 (EP) 06405369.7

(51) Int. Cl. G03F 7/12; B41C 1/14

(52) U.S. Cl. 101/128.4; 430/308

(57) ABSTRACT

An exposure device for the production of screen-print stencils has a holder for the stencil, an exposure system with a light source, and a lens system in an exposure head that is movable. A signal source that yields digital signals is connected with the exposure system. The light source is a number n of laser diodes that work in the wavelength range of 300-450 nm. Several modules comprising groups of laser diodes are present on the exposure unit and can be controlled by the signals of the signal source. The light signals of the laser diodes are guided to a raster plate in the exposure head, by light-guiding fibers. The light output of the raster plate is passed to a focusing lens system in the exposure head, which is adapted to the laser diodes in terms of the wavelength range.

### BACKGROUND OF THE INVENTION

1. Field of the Invention

The invention relates to an exposure device for the production of screen-print stencils. The invention particularly relates to an exposure device for the production of screen-print stencils, having a holder for the screen-print stencil, an exposure system that has at least one light source that produces a beam of light, and a lens system, in an exposure head. There is a signal source that yields digital signals, which is connected with the exposure system in such a manner that the entire screen-print stencil can be exposed in accordance with the signals. The exposure head can be moved relative to the screen-print stencil. This is therefore a device for implementing a so-called cts (computer-to-screen) method, in other words a device in which the data to be transferred to the artwork (screen-print stencils) are controlled by the digital signals of a computer, and made available by way of an optical exposure system.

2. The Prior Art

A method for the production of screen-print molds as well as an exposure device for it, which has the characteristics indicated above, is described in European Patent No. EP-0 953 877. In the case of this device, the exposure system has a micromechanical mirror system that is provided with a plurality of micromirrors, which are at least partly movable. Such micromechanical mirror systems are also known as so-called DMDs (digital micromirror devices) and are commercially available. In the case of the present application, the micromechanical mirror system serves to deflect and modulate a beam of light in such a manner that the position of the movable micromirrors can be changed, as a function of the signals of a computer, so that the mirrored part of each beam of light either goes into the light output or not. Here, of course, the light output means the light deflected towards the screen-print mold or screen-print stencil. Here, a steady-burning light is used as the light source, for example electrode-free UV emitters that are excited by microwaves. Furthermore, the holder with the screen-print mold and the exposure system can also be moved relative to one another.

Despite the current widespread use of DMD modules (for example for beamers), however, the device according to European Patent No. 0 953 877 has some important disadvantages. Since the DMDs are mechanically moved mirror systems, there are, of course, certain limits with regard to changes in the beam of light to be modulated that take place very quickly. Common DMDs have a limit frequency of about 20 kHz, which, of course, severely limits the “image production speed” for the screen-print stencils. In total, according to information from the manufacturer (CST), maximal image production speeds in the range of approximately 500 square feet/hour are achieved at 65 lpi for relevant devices (of course, this is true only for “fast” emulsion types and a slight stencil thickness). The image production speed that can be achieved is, of course, also determined by the radiation energy to be expended (depending on the stencil/emulsion material on which the image is to be produced, some very different amounts of radiation energy are required). Here again, limits are set for the use of DMDs, because relatively high losses always occur due to the use of mirrors (the “reflected-away” parts of the beam of light manifest themselves in the form of relatively great heat loss, which must be carried away).

Finally, a continuous radiation source that works with high power must be used as the light source, and this again is expensive and related to relatively great power losses (because only part of the energy supplied is actually converted to usable radiation). Thus, again according to information from the manufacturer, UV light sources having a power of usually 600-1200 watts are used, and these again require special cooling.

### SUMMARY OF THE INVENTION

It is therefore the object of the invention to indicate an improved exposure device for the production of screen-print stencils.

This object is accomplished by an exposure device for the production of screen-print stencils, having a holder for the screen-print stencil, an exposure system that has at least one light source that produces a beam of light, and a lens system, in an exposure head. There is a signal source that yields digital signals, which is connected with the exposure system in such a manner that the entire screen-print stencil can be exposed in accordance with the signals. The exposure head can be moved relative to the screen-print stencil and the light source has a number n of similar laser diodes that work in the wavelength range of 300-450 nm, which can be controlled by the signals of the signal source. The light signals of the laser diodes are guided to a raster plate in the exposure head by way of a similar number n of light-guiding fibers. The light output of the raster plate is passed to a focusing lens system in the exposure head, which system is adapted to the laser diodes in terms of the wavelength range.

The use of laser diodes that can be modulated directly has various significant advantages. For one thing, the need for continuous operation is eliminated, and thus, the power loss of the entire exposure device can be significantly reduced. Furthermore, there are almost no upper limits on the reaction speed of laser diodes (at least in the area of application that is of interest here, that of exposing screen-print stencils), because the limit values that can be reached lie in the GHz range. Furthermore, because the laser diodes are easy to control, and there are no light-deflecting mirrors in the beam path, another case of undesirable power loss is eliminated, specifically because no additional losses have to be accepted, with the exception of absorption losses in the materials in the beam path (lens system components).

Since a number of laser diodes must be used for the solution according to the invention, and laser diodes that can be used for the purpose of image production on the desired substrate materials must also work in a wavelength range of 300-450 nm, such solutions were not even considered until now, for cost reasons, among others. However, high-power blue laser diodes that work in the wavelength range of 405 nm have been commercially available (from Nichia) at relatively low cost. Furthermore, a significant price decline for blue laser diodes must be expected because of the increased occurrence of new DVD technologies, in which blue laser diodes are also used, so that the solution according to the invention is becoming increasingly attractive as compared with the DMD solution and similar solutions.

Furthermore, it must also be pointed out that in the case of DMD solutions (in other words in the case of micromirror chips), selected chips must always be used (since all of the pixels must be fully functional), and even DMD chips with a high pixel count that are produced in large numbers are still expensive, which makes the solution according to the invention appear attractive, particularly if, as provided, the proposed exposure device is structured in such a manner that the number of laser diodes used is expandable. In terms of software, i.e. on the side of the signal source or the control computer, such expandability is relatively easy to implement, with regard to the adaptability of the control program to be used (for example with twice the number of laser diodes). Furthermore, with this measure, one gains the advantage that devices can be offered in different price classes and performance classes.

The exposure device according to the invention can furthermore be used both for the production of flat screen-print stencils and for the production of cylindrical screen-print stencils.

However, a raster arrangement of light sources that can be controlled individually (in this case, the laser diodes) is of central importance for exposure devices of this type. In this connection, the laser diodes themselves do not yet necessarily have to be mounted in the raster arrangement required for exposure of the stencil material. Instead, it is sufficient to guide the light-guiding fibers to a raster plate in the exposure head, and to structure the raster plate itself in such a manner that the light-guiding fibers appear there in the raster arrangement that is necessary for exposure of the stencil material. The raster plate is therefore a fiber array that accommodates the light-guiding fibers and orients them parallel to the optical axis of the focusing lens system, in a rectangular or trapezoid-like raster arrangement. Since it is provided that the light-guiding fibers are structured so that they can be plugged in on both sides, in other words both at the connectors to the laser diodes and at the connectors to the raster plate, there are advantages with regard to flexibility and ease of maintenance.

The raster plate in the raster arrangement therefore makes available a number n of light beams of the laser diodes oriented parallel to the optical axis of the focusing lens system, whereby the beam diameter of the individual light beams essentially corresponds to the diameter of the light-guiding fiber, and the task of the focusing lens system consists of producing an image of this raster arrangement that is reduced in size or enlarged, on the stencil material on which the image is to be produced (to be exposed). In order to be able to balance out uneven areas of the stencil material during operation, the focusing lens system is preferably also equipped with an auto-focusing device.

The proposed exposure device according to the invention can be implemented particularly well in the case of an exposure unit structured using the portal construction method. Such exposure units are often disposed vertically, i.e. the holder for the screen-print stencil lies in a vertical plane, because of the size of the screen-print stencils to be exposed, in order to save space. In this connection, the exposure unit, together with a control unit and a computer unit, forms the exposure device for the production of screen-print stencils. It is advantageous, in this connection, if the laser diodes and the light-guiding fibers are disposed so that they can be plugged into modules in an interface part that conduct heat away.

In this connection, the interface part, with the modules, is disposed on the exposure device in such a manner that it performs the movements of the exposure head only in a movement direction required for exposure of a stencil material, in order to keep the mass that must be moved for an exposure procedure as small as possible. This is the case, for example, if the interface part, with the modules, is disposed on the portal arm of an exposure table structured using the portal construction method. The interface part then goes along with the relatively slow movements of the exposure head in the X direction (movement direction of the portal arm), but not the relatively fast movements of the exposure head in the Y direction (movement direction of the exposure head on the portal arm). Alternatively, it would also be possible to affix the interface part, with the modules, on the exposure unit. The interface part, with the modules, would then not perform any of the movements of the exposure head in the movement directions required for exposure of a stencil material.

Another advantage of the exposure device according to the invention lies is that less expensive lens systems can be used in the exposure head, because of the possibility of using a focusing lens system that is adapted to the laser diodes in terms of the wavelength range. This is because if the work is carried out using light sources having a broader spectral distribution than in the case of laser diodes, the lens system must also be optimized for the entire spectral range to be covered, because of the required focusing accuracy. Since it is also provided, in the case of the exposure device according to the invention, that the exposure lens systems are structured so that they can be replaced or switched over with little effort, the device can very easily be converted to the processing of stencil material having different requirements with regard to spectral sensitivity.

The new machine concept therefore has very significant advantages as compared with the current machine concepts, particularly with regard to convertibility, ease of maintenance, and expandability.

### BRIEF DESCRIPTION OF THE DRAWINGS

Other objects and features of the present invention will become apparent from the following detailed description considered in connection with the accompanying drawing. It is to be understood, however, that the drawing is designed as an illustration only and not as a definition of the limits of the invention.

In the drawing:

FIG. 1 shows an exposure device for the production of screen-print stencils, using the portal construction method.

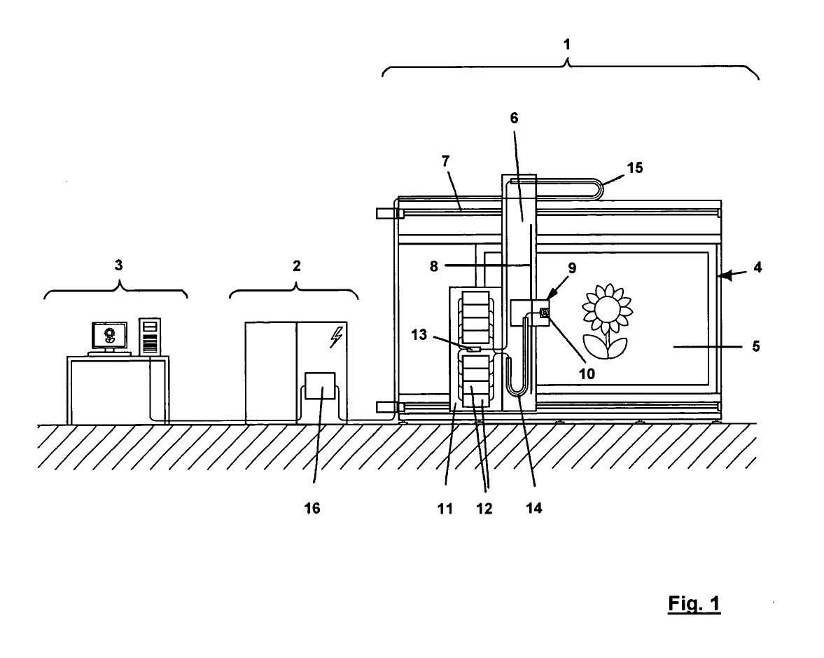

### DETAILED DESCRIPTION OF THE PREFERRED EMBODIMENT

An exposure device for the production of screen-print stencils is structured using the portal construction method and consists essentially of an exposure unit 1, a control unit 2, and a computer unit 3.

Exposure unit 1 comprises a vertically disposed processing table having a holder 4 for screen-print stencils 5 (to be exposed). A portal arm 6 can be moved on an X axis guide 7, in an X direction, above holder 4 and the screen-print stencil. An exposure head 9 having a focusing lens system 10 with an auto-focusing device 19 can be moved in a Y direction on portal arm 6, on a Y axis guide 8. The X direction therefore corresponds to the movement direction of portal arm 6. Precision guides and precision drives (not shown) are present both for the movement in the X direction and for the movement in the Y direction.

An interface part 11 is attached to portal arm 6. Several modules 12 that conduct heat away are situated on interface part 11; they have groups of laser diodes 20 as well as a data distributor 13 and interface electronic components (not shown). The digital signals that come from computer unit 3 as the signal source are converted into optical signals in the interface part. Since exposure head 9 is disposed to be movable with regard to modules 12 with laser diodes 20, the signals from laser diodes 20 are transmitted to exposure head 9 by way of light-guiding fibers 21, by way of a Y drag chain 14.

For example, four to eight modules 12 having groups of 16 laser diodes 20 each can be disposed on the interface part in this manner. This then yields a total number n of 64 to 128 laser diodes 20, whereby the light output of each laser diode 20 is passed to raster plate 18 in the exposure head 9 by way of a separate light-guiding fiber 21, by way of the Y drag chain 14. In this connection, it is advantageous if the laser diodes 20 work in a wavelength range of 300-450 nm, preferably in the blue-light range at 405 nm. Laser diodes 20 are used in directly modulated operation, i.e. they are directly controlled by a digital signal, in the usual manner.

Since portal arm 6 with interface part 11 is also movable with regard to the processing table, i.e. holder 4, signals are transmitted to data distributor 13 by way of an X drag chain 15. In contrast to Y drag chain 14, however, the signals and power feeds for the control and movement of exposure head 9 in the Y direction are also carried along here.

In the case of devices of this type, a screen-print stencil 5 accommodated in holder 4 is completely or partially exposed by movements of the exposure head in the X direction and Y direction. The movement in the X direction generally takes place more slowly than the movement in the Y direction, because only a very much smaller mass has to be moved in the Y direction.

The function of control unit 2 essentially consists in controlling the movements of exposure head 9 in the X direction and Y direction. The functions required for this are advantageously implemented in a memory-programmable control 16 (PLC unit). Control unit 2 also contains the driver circuits required for controlling movement, etc.

Finally, the data to be exposed onto a screen-print stencil 5 are made available by computer unit 3 (signal source), and the exposure procedure is controlled by the latter. Both the functions of computer unit 3 and the functions of the control unit 2 are well known to a person skilled in the art from devices of this type, and therefore require no further explanation here.

In the new machine concept according to the above description, the greatest possible flexibility can be achieved with various individual measures, for example with:
Consistent implementation of the modular concept for the laser diodes, whereby a fixed number of laser diodes of a desired type is present per module 12 in interface part 11, in each instance. In this way, the image production speed of the exposure device can be increased in simple manner by installation of additional modules (expandability/power increase).
Light-guiding fibers that can be plugged in on both sides, between modules 12 and the raster plate in exposure head 9. This not only facilitates ease of maintenance of the system, but also facilitates its expandability.
With the interchangeability of the focusing lens system 10 in exposure head 9. Very different materials for the screen-print stencils can actually be processed in that focusing lens systems are used together with the desired laser diodes, which systems are coordinated with the wavelength range of the laser diodes used.

In total, a price-advantageous, high-performance, expandable system with which fundamentally all the usual materials for screen-print stencils can be processed is obtained with the exposure device for the production of screen-print stencils, according to the invention.

Accordingly, while only a few embodiments of the present invention have been shown and described, it is obvious that many changes and modifications may be made thereunto without departing from the spirit and scope of the invention.

What is claimed is:

1. An exposure device for the production of screen-print stencils, comprising:
a holder for the screen-print stencil;
an exposure system that has at least one light source that produces a beam of light, said light source having a number n of similar laser diodes that work in a wavelength range of 300-450 nm;
a focusing lens system in an exposure head, said exposure head being movable relative to the screen-print stencil;
a signal source that yields digital signals that control said diodes, said signal source being connected with the exposure system so that the entire screen-print stencil is exposed to the at least one light source in accordance with the signals;
wherein light signals of the laser diodes are guided to a raster plate in the exposure head by way of a number n of light-guiding fibers, and
wherein light output of the raster plate is passed to said focusing lens system in the exposure head, which system is adapted to the laser diodes in terms of wavelength range.

2. An exposure device according to claim 1, wherein the exposure device is adapted to produce flat screen-print stencils and cylindrical screen-print stencils.

3. An exposure device according to claim 1, wherein the laser diodes are directly modulated laser diodes.

4. An exposure device according to claim 3, wherein the laser diodes work in a pulsed energy range of >30 mW to make images on all commercially available stencil materials.

5. An exposure device according to claim 3, wherein the laser diodes work in a blue-light range at 405 nm.

6. An exposure device according to claim 1, wherein the number n of laser diodes used can be expanded.

7. An exposure device according to claim 1, wherein the laser diodes and the light-guiding fibers are adapted to be plugged into heat-removing modules in an interface part.

8. An exposure device according to claim 7, wherein the interface part with the modules does not move with movement of the exposure head, or moves only in movement directions required for exposing a stencil material, in order to keep mass to be moved for an exposure procedure as small as possible.

9. An exposure device according to claim 8, wherein the interface part with the modules is disposed on a portal arm of the exposure unit structured using a portal construction method.

10. An exposure device according to claim 1, wherein the raster plate is a fiber array that accommodates the light-guiding fibers and orients said light-guiding fibers parallel to an optical axis of the focusing lens system, in a rectangular or trapezoid-like raster arrangement.

11. An exposure device according to claim 10, wherein the raster plate makes a number n of light beams of the laser diodes, oriented parallel to the optical axis of the focusing lens system, available in the raster arrangement, wherein a beam diameter of individual light beams essentially corresponds to a diameter of the light-guiding fibers, and wherein the focusing lens system makes available an image of the raster arrangement that is reduced in size or enlarged, on the stencil material on which the image is to be produced.

12. An exposure device according to claim 11, wherein the focusing lens system has an auto-focusing device.
